(19) United States
(12) Patent Application Publication
(10) Pub. No.: US 2010/0072578 A1
(43) Pub. Date: Mar. 25, 2010

(54) Semiconductor chip and semiconductor wafer

(75) Inventor: Hiroyuki Kunishima, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 12/585,393

(22) Filed: Sep. 14, 2009

(30) Foreign Application Priority Data
Sep. 22, 2008 (JP) 243315/2008

(51) Int. Cl. H01L 23/544

(52) U.S. Cl. 257/620; 257/E23.179

(57) ABSTRACT

A semiconductor chip which includes an element forming region formed over a substrate, a scribe line region which surrounds the element forming region, and a structure provided locally inside the scribe line region in at least one corner area of the semiconductor chip. The element forming region and the scribe line region include a plurality of interlayer dielectric films laminated over the substrate. The structure is constituted of corner pads sandwiching at least one of the interlayer dielectric films vertically in the direction of lamination, and vias interconnecting the corner pads.

### FIELD OF THE INVENTION

The present invention relates to semiconductor chips, semiconductor wafers, and wafer dicing methods for manufacturing semiconductor chips.

### BACKGROUND OF THE INVENTION

In connection with the present invention, JP-A No. 2007-067372 discloses a technique for semiconductor devices that seal rings which entirely surround an element forming region are provided between the element forming region and a scribe line region to prevent chipping caused by semiconductor wafer dicing from reaching the inside of the element forming region. The seal rings, intended to prevent water penetration into the element forming region, are disposed around the element forming region along its border.

As another technique related to the present invention, JP-A. 56(1981)-140626 describes a technique for semiconductor wafers that mask aligning patterns (alignment marks) such as cross marks for positioning of element forming regions are disposed in scribe line regions.

FIG. 11 is a schematic plan view showing an alignment mark and its vicinity in a semiconductor wafer in enlarged form. FIG. 12 is a sectional view, taken along the line XII-XII in FIG. 11, which shows the layered structure of the semiconductor wafer.

The semiconductor wafer 112 has rectangular element forming regions 20 arranged in a specific pattern and scribe line regions 30 lying between element forming regions 20. A seal ring region 25 lies between an element forming region 20 and a scribe line region 30.

An alignment mark 40, a cross-shaped mark with a metal membrane (aluminum, etc), lies in an intersection where scribe regions 30 meet.

As shown in FIG. 12, in the element forming region 20 and scribe line region 30, interlayer dielectric films 22 are laminated over a substrate 16. The element forming region 20 includes an internal circuit region with metal wirings 210 made by patterning and an I/O (Input/Output) region.

A barrier film 23 lies on the upper face of each interlayer dielectric film 22.

The seal ring region 25 is a region in which seal rings 251 for surrounding an element forming region 20 are formed by connecting ring pads 211 and seal walls 24.

Ring pads 211, constituting the seal rings 251, lie in the same layers as the metal wirings 210 inside the element forming region 20, forming a band which runs around the border of the element forming region 20 like a rectangular frame. The stacked ring pads 211 are connected with each other by seal walls 24 which run around the element forming region 20 similarly.

The upper surfaces of the scribe line region 30, element forming region 20 and seal ring region 25 are covered by a transparent surface-protective film 42.

### SUMMARY OF THE INVENTION

In the dicing process where a semiconductor wafer is diced into semiconductor chips, element forming regions are separated from each other into pieces by making cuts in scribe line regions.

In this process, an impact given by cutting may cause peeling, breaking or cracking of a metal layer such as an alignment mark and an interlayer dielectric film in the semiconductor wafer (hereinafter such damages are collectively referred to as “chipping”).

Chipping would destroy seal rings and permit water penetration into the element forming region or damage the element forming region, resulting in deterioration in electric characteristics of the semiconductor chip.

In addition, chipping not only occurs in the semiconductor wafer dicing process but also may occur in the process of transporting or handling semiconductor chips as separate pieces. In the latter process, chipping due to stress concentration are likely to occur in semiconductor chip corner areas.

On the other hand, in recent years, there has been a growing demand for smaller element formation regions and higher efficiency of use of the semiconductor wafer, namely an increase in the area ratio of element forming regions. This means that it is becoming more difficult to provide a sufficiently wide seal ring region around the element forming region or widen the scribe line region to get a sufficient spacing between a dicing line and the seal ring region.

For example, in the semiconductor wafer described in JP-A No. 2007-067372, auxiliary portions like ribs are arranged along the inside of the seal ring region radially from the element forming region to reinforce the seal rings and prevent chipping from spreading into the element forming region. However, the presence of such auxiliary portions means that the scribe line region width is increased by the auxiliary portion length, leading to a lower efficiency of use of the semiconductor wafer.

As discussed above, it has been expected to prevent chipping in a scribe line region from spreading into an element forming region of a semiconductor wafer while ensuring highly efficient use of the wafer.

According to an aspect of the present invention, a semiconductor chip includes an element forming region formed over a substrate, and a scribe line region formed over the substrate which surrounds the element forming region, where the element forming region and the scribe line region include plural interlayer dielectric films laminated over the substrate and a structure, constituted of plural corner pads sandwiching at least one of the plural interlayer dielectric films vertically in the direction of lamination and vias interconnecting the corner pads, is provided locally in the scribe line region in at least one corner area of the semiconductor chip.

Here, the element forming region means a region of the semiconductor chip in which an internal circuit is formed. The scribe line region means a region around the element forming region and includes corner areas of the semiconductor chip. The corner area of the semiconductor chip means a region which includes a corner of the semiconductor chip and has a given expanse.

The expression “(a structure is) provided locally in the scribe line region in at least one corner area of the semiconductor chip” is meant to exclude the possibility that a structure stretches all over the scribe line region or stretch continuously over two or more corner areas.

In other words, the structure may stretch over the whole or part of one corner area or over the whole or part of each of two or more corner areas.

According to an aspect of the present invention, a semiconductor wafer includes plural element forming regions formed over a substrate and belt-like scribe line regions formed over the substrate which intersect each other and respectively surround the element forming regions. The element forming regions and the scribe line regions include plural laminated interlayer dielectric films and a structure is provided locally in an intersection of scribe line regions where the structure is constituted of plural pads sandwiching at least one of the interlayer dielectric films vertically in the direction of lamination, and vias interconnecting the pads.

From an investigation by the inventors it has been found that chipping caused by semiconductor wafer dicing usually occurs in intersections where scribe line regions meet. How it occurs is explained below.

An explanation is given based on assumption that a semiconductor wafer is diced along two intersecting directions (first and second directions) to separate the element forming regions. In the step of dicing the wafer along the first direction, since neighboring element forming regions are connected through their edges extending in the second direction, the impact of dicing is not concentrated in individual element forming regions. Thus, in the first dicing step, the semiconductor wafer is diced into strips without chipping.

On the other hand, in the second step of dicing where semiconductor wafer strips are cut along the second direction to make separate semiconductor chips, a cut is made along the last or uncut edge of each element forming region which has the other three edges already cut. Therefore, just before the element forming region is completely cut off, it is unstably and narrowly connected with an adjacent element forming region only in one corner area which serves as a dicing stroke end. Thus the impact given by the dicing blade is concentrated in that corner area, so cracking or chipping easily occurs in the uncut part before the dicing blade passes it.

For the above reason, chipping easily occurs in an intersection of a scribe line region which serves as a dicing stroke end.

Therefore, according to the present invention, since a structure constituted of corner pads interconnected by vias is provided in a corner area of the semiconductor chip, spread of chipping into the element forming region is prevented when a dicing stroke is ended at the corner area.

In other words, in the semiconductor wafer, chipping does not occur in the process of dicing it into semiconductor chips. Since the corner pads and vias are located in a corner area of the scribe line region, the effective area of the element forming region is not affected and high efficiency of use of the semiconductor wafer is maintained.

The semiconductor chip improves the yield rate in the dicing process and enhances productivity.

According to the semiconductor chip, it is possible to prevent chipping due to an impact given after the dicing process in a corner area.

A semiconductor wafer dicing method according to the present invention is a process of dicing a semiconductor wafer which includes plural element forming regions formed over a substrate, and belt-like scribe line regions formed over the substrate which intersect each other and respectively surround the element forming regions, where the wafer is diced into semiconductor chips including the element forming regions respectively. The element forming region and the scribe line region include plural interlayer dielectric films laminated over the substrate; a structure, constituted of plural metal pads sandwiching at least one of the interlayer dielectric films vertically in the direction of lamination and vias interconnecting the pads, is locally provided in at least one intersection of the scribe line region; and the element forming regions are separated using an intersection embracing the above structure as a dicing stroke end.

In the above dicing method, the use of an intersection embracing the structure as a dicing stroke end prevents spread of chipping which would otherwise easily occur in the intersection.

In the present invention, various elements need not be each independent and more than one element may constitute a single member or a single element may be constituted of more than one member or a certain element may be part of another element or part of one element may be part of another element.

In the explanation of the semiconductor wafer dicing method according to the present invention, a certain sequence of steps may be described but the sequence does not limit the sequence in which the steps are carried out, unless otherwise specified. Several steps need not be carried out at different times but a certain step may be started while another step is in progress or a period in which a certain step is carried out wholly or partially overlaps a period in which another step is carried out.

The semiconductor wafer according to the present invention and the dicing method therefor prevent spread of chipping into an element forming region in the dicing process while maintaining high efficiency of use of the semiconductor wafer, and thus offer high quality semiconductor chips.

The semiconductor wafer according to the present invention improves productivity in the dicing process and prevents spread of chipping in corner areas after the dicing process.

### BRIEF DESCRIPTION OF THE DRAWINGS

FIG. 1 is a plan view of a semiconductor wafer according to a first embodiment of the present invention;

FIG. 2 is a plan view of an intersection of scribe line regions and its vicinity;

FIG. 3 is a sectional view of the layered structure of the semiconductor wafer;

FIGS. 4A and 4B are schematic plan views of a semiconductor chip, in which FIG. 4A shows a semiconductor chip and FIG. 4B shows a corner area of the chip;

FIGS. 5A to 5D are schematic plan views of various variations of vias in an intersection of a semiconductor wafer according to a second embodiment of the invention, in which FIG. 4A shows a first variation, FIG. 4B a second variation, FIG. 5B a third variation, and FIG. 5D a fourth variation;

FIGS. 6A and 6B are schematic plan views of an anti-chipping structure in a semiconductor wafer according to a third embodiment of the invention, in which FIG. 6A shows a combination of sub-pads and FIG. 6B shows another combination of sub-pads;

FIG. 7 is a sectional view of the layered structure of a semiconductor wafer according to a fourth embodiment of the invention;

FIG. 8 is a sectional view of the layered structure of a semiconductor wafer according to a fifth embodiment of the invention;

FIG. 9 is a sectional view of the layered structure of a semiconductor wafer according to a sixth embodiment of the invention;

FIG. 10 is a schematic plan view of an anti-chipping structure in a semiconductor wafer according to a seventh embodiment of the invention;

FIG. 11 is a schematic plan view showing an alignment mark and its vicinity in a conventional semiconductor wafer;

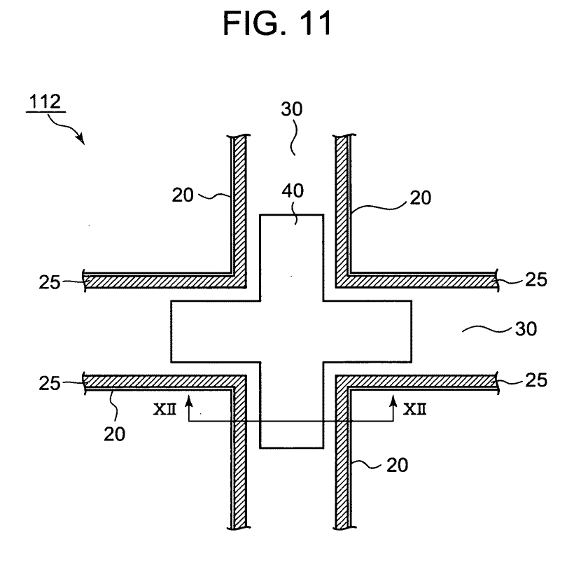

FIG. 12 is a sectional view of the layered structure of a semiconductor wafer; and

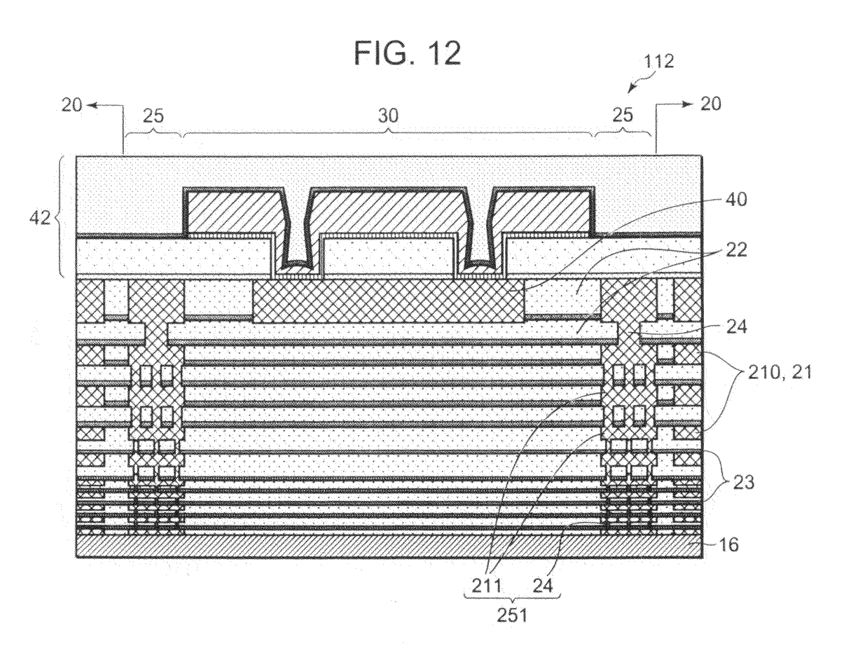

FIG. 13 is a plan view of a semiconductor wafer.

### DETAILED DESCRIPTION OF THE PREFERRED EMBODIMENTS

Next, the preferred embodiments of the present invention will be described referring to the accompanying drawings. In all the drawings, like elements are designated by like reference numerals and repeated descriptions of such elements are omitted as appropriate.

### First Embodiment

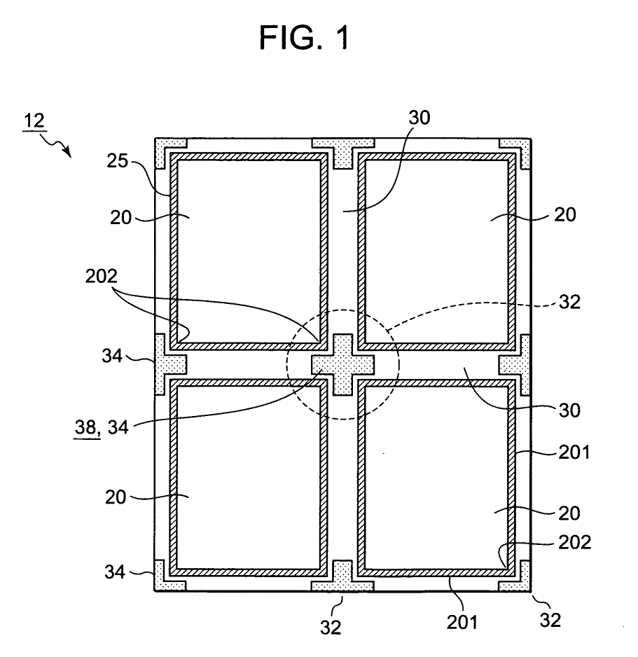

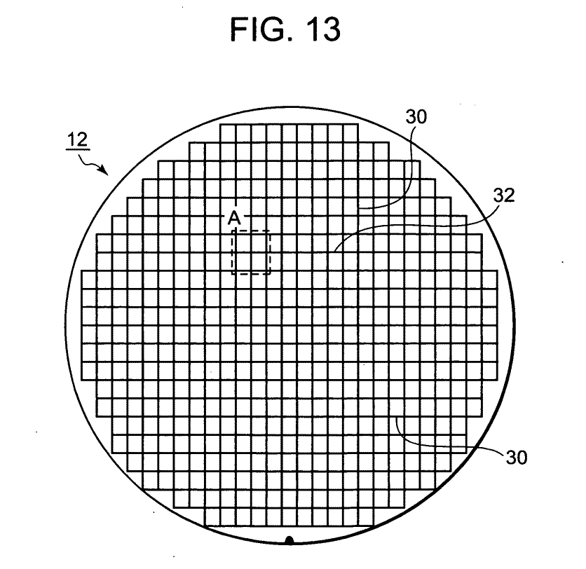

FIG. 1 is a plan view showing, in enlarged form, an area enclosed by dotted line A in a semiconductor wafer 12 shown in FIG. 13 according to the first embodiment. For illustration, seal ring regions 25 and reinforcing pads 34 are indicated by hatching in the figure.

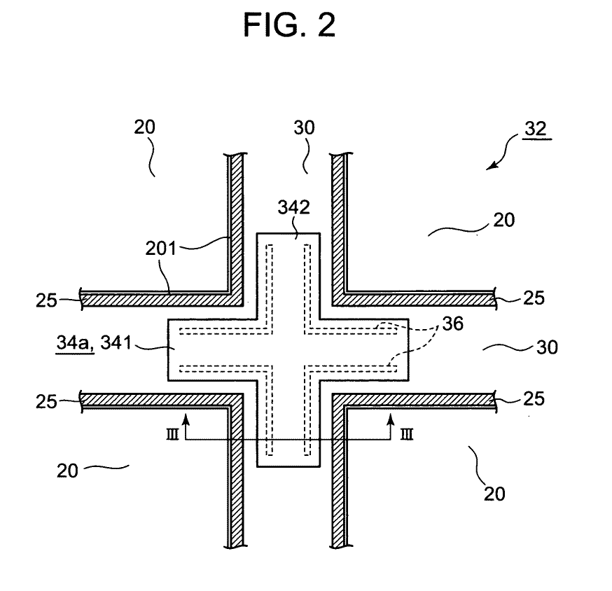

FIG. 2 is an enlarged plan view showing an intersection 32 of scribe line regions 30 and its vicinity which correspond to the intersection 32 and its vicinity as enclosed by chain line in FIG.1.

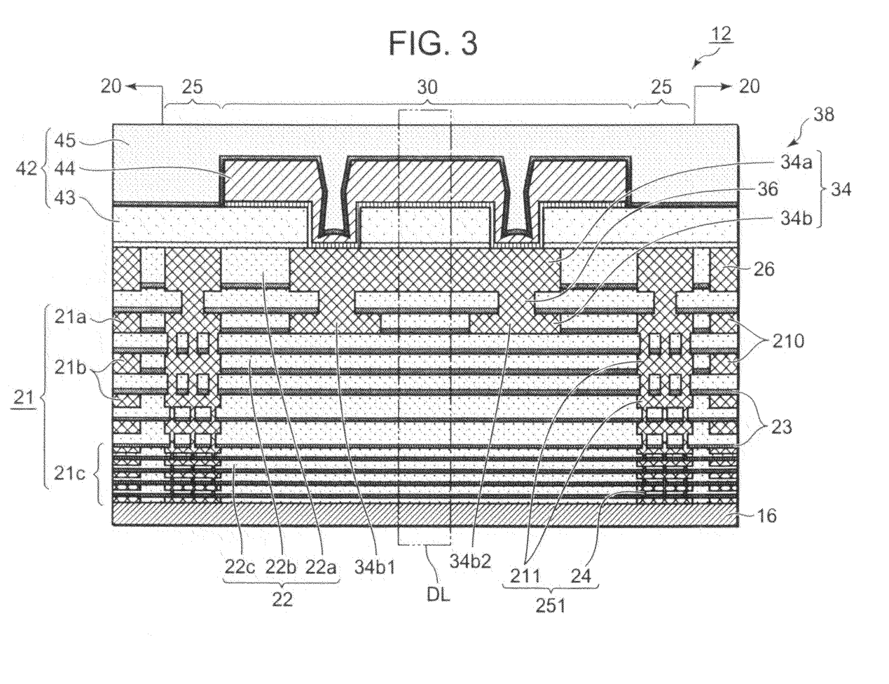

FIG. 3 is a sectional view showing the layered structure of the semiconductor wafer 12, taken along the line in FIG.2.

[Semiconductor Wafer]

First, the semiconductor wafer 12 in this embodiment is summarized below.

The semiconductor wafer 12 includes plural element forming regions 20 and belt-like scribe line regions 30 intersecting each other and respectively surrounding the element forming regions 20.

In the element forming regions 20 and scribe line regions 30, plural interlayer dielectric films 22 are laminated.

The semiconductor wafer 12 also includes a structure (anti-chipping structure 38) which is constituted of plural pads (reinforcing pads 34) lying locally in an intersection 32 of scribe line regions 30 and sandwiching at least one of the interlayer dielectric films 22 vertically in the direction of lamination (vertical direction in FIG. 3) and vias 36 interconnecting the reinforcing pads 34.

In the semiconductor wafer 12, the element forming regions 20 are arranged in rows vertically and horizontally. For simple illustration, FIG. 1 only shows two element forming regions in each of the vertical and horizontal rows, four element forming regions in total, though the semiconductor wafer 12 may have hundreds or thousands of element forming regions 20 arranged thereon vertically and horizontally. The shape of each element forming region of the semiconductor wafer 12 as viewed from above is not limited to the rectangle as shown in the figure; alternatively it may be circular.

Belt-like scribe line regions 30 in which cuts are made by a dicing blade are formed between neighboring element forming regions 20 and around element forming regions 20.

A dicing line DL is indicated by chain double-dashed line in FIG. 3.

In the semiconductor wafer 12 according to the first embodiment, a seal ring region 25 lies between an element forming region 20 and a scribe line region 30, surrounding the element forming region 20.

The seal rings 251 which constitute the seal ring region 25 include ring pads 211 and seal walls 24 which are connected to cover the entire periphery of the element forming region 20. The seal rings 251 are not cut off in the dicing process but remain as inherent regions of the semiconductor chip 10.

Therefore, the semiconductor wafer 12 includes the seal ring region 25 which lies between an element forming region 20 and a scribe line region 30 and surrounds the element forming region 20, as well as the anti-chipping structure 38 which lies in an intersection 32 of the scribe line region 30.

In this embodiment, since the element forming region 20 is rectangular, the scribe line region 30, stretching along the edges 201 of an element forming region 20, extends in two mutually orthogonal directions. A corner 202 of an element forming region 20 is adjacent to an intersection 32 at which scribe line regions 30 meet. As illustrated in FIG. 1, there are three types of intersection 32: an L-shaped intersection adjacent to only one corner area 202 of an element forming region 20, a T-shaped one adjacent to two corner areas 202, and a cross-shaped one adjacent to four corner areas 202.

In the semiconductor wafer 12, an anti-chipping structure 38 is provided in an intersection 32. The anti-chipping structure 38 should be provided in an intersection 32 adjacent to at least one corner 202 of each element forming region 20. Therefore, in the semiconductor wafer 12, as shown in FIG. 1, an anti-chipping structure 38 maybe provided in the intersection 32 as a gathering point for corners 202 of the four element forming regions 20 adjacent to each other vertically and horizontally.

In this embodiment, an anti-chipping structure 38 is provided in every intersection 32 of the scribe line regions 30, as illustrated in FIG. 1.

As illustrated in FIGS. 2 and 3, the anti-chipping structure 38 includes reinforcing pads 34 with an interlayer dielectric film 22 between them and vias 36 interconnecting them in the thickness direction.

The reinforcing pads 34 lie locally in the scribe line regions 30. More specifically, they stretch over the whole or part of an intersection 32 of scribe line regions 30.

In the semiconductor wafer 12, interlayer dielectric films 22, barrier films 23 and metal wiring layers 21 are repeatedly stacked over a substrate 16 of silicon, glass or the like.

The interlayer dielectric films 22 and barrier films 23 are continuously formed in both the element forming regions 20 and scribe line regions 30.

In the explanation of this embodiment, “vertical” in the direction of lamination of the semiconductor chip 10 or semiconductor wafer 12 suggests a positional relation in which the substrate 16 is in a lower position and the metal wiring layers 21 are in an upper position but does not suggest the direction of gravitational force.

An insulating material is used for the interlayer dielectric films 22. The insulating material may be a low-k material (material with a low dielectric constant) or non low-k material depending on the required dielectric constant.

Low-k materials include: SiOC (carbon-containing silicon carbide); polyhydrogen siloxane such as HSQ (hydrogen silsesquioxane), MSQ (methyl silsesquioxane) and MHSQ (methyl hydrogen silsesquioxane); poly aryl ether (PAE); divinyl siloxane-bis-benzocyclobutene (BCB); aromatic organic materials such as Silk (registered trademark); and organic materials such as SOG, FOX (registered trademark) (flowable oxide), and CYTOP (registered trademark).

If the interlayer dielectric films 22 are required to have a low dielectric constant, it is recommended that porous materials among the above listed low-k materials, for example, porous SiOC (p-SiOC) be used.

If the interlayer dielectric films 22 are permitted to have a relatively large dielectric constant, a non-low-k material maybe used. Non-low-k materials include inorganic insulating materials such as silicon oxide (SiO₂).

[Element Forming Region]

The element forming region 20 includes an internal circuit region in which various circuit patterns are formed by metal wirings 210, and an I/O (Input/Output) region.

The metal wiring layer 21 is a layer which includes patterned metal wirings 210. In this embodiment, the metal wirings 210, made of copper or other metal, is locally buried in interlayer dielectric films 22. This means that the interlayer dielectric films 22 and metal wiring layers 21 partially overlap in the direction of lamination.

As illustrated in FIG. 3, concerning the metal wiring layers 21, the lower local wiring layers 21c near the substrate 16 are thin, the intermediate semi-global wiring layers 21b are moderately thick and the upper global wiring layers 21a are thick.

Accordingly, in terms of the thickness of an interlayer dielectric film 22 placed between metal wiring layers 21, the lower dielectric films 22c are thin, the intermediate dielectric films 22b are moderately thick, and the upper dielectric films 22a are thick.

In this embodiment, a porous low-k material with a low dielectric constant is used for the lower dielectric films 22c and a non-porous low-k material for the intermediate dielectric films 22b and a non-porous non-low-k material for the upper dielectric films 22a.

These insulating materials are more fragile than metallic materials and when they are used, chipping easily occurs and spreads during dicing.

Each barrier film 23 is a single layer film made of an inorganic material such as TiN (titanium nitride), Ta (tantalum), TaN (tantalum nitride), W (tungsten) or WN (tungsten nitride), or a laminated film of any combination of these materials.

Metal pads 26 are buried in the uppermost interlayer dielectric film 22. The metal pads 26 are made of a metallic material such as aluminum or TiN.

The metal pads 26 and metal wirings 210 are connected by seal walls 24 in the thickness direction to constitute a seal ring 251.

Each metal pad 26 is exposed in a given place inside an element forming region 20 and visible from above.

A transparent surface-protective film 42 lies over the top surface of the element forming region 20. In this embodiment, the surface-protective film 42 includes plural laminated layers. More specifically, a silicon oxide film 43 (SiO₂), silicon oxide nitride film 44 (SiON) and polyimide film 45 are stacked from bottom to top in order.

[Scribe Line Region]

In the scribe line regions 30, metal pads (reinforcing pads 34) which sandwich an interlayer dielectric film 22 vertically are stacked. The reinforcing pads 34 (34a and 34b) lie in the same layers as the metal pad 26 and the global wiring layer 21a, namely the uppermost metal wiring layer 21, respectively.

In other words, in this embodiment, plural interlayer dielectric films 22 are laminated in each scribe line region 30 and some of the interlayer dielectric layers 22 are vertically sandwiched by reinforcing pads 34 interconnected by vias 36.

In this embodiment, the element forming region 20 has wirings (metal wirings 210) in plural interlayer dielectric films 22 and the reinforcing pads 34a and 34b in the scribe line region 30 lie in the same layers as the metal wiring layers 210.

The reinforcing pads 34a and 34b are made of the same material as the metal wirings 210. In other words, in this embodiment, the upper reinforcing pad 34a is made of aluminum and the lower reinforcing pad 34b is made of copper.

The reinforcing pads 34 (34a and 34b) are placed at such a height level that the uppermost interlayer dielectric film 22 is vertically sandwiched by them.

However, the height level at which the reinforcing pads 34 are placed may be varied, which will be described in detail later.

The reinforcing pads 34a and 34b are interconnected by vias 36 to constitute an anti-chipping structure 38.

The vias 36 are made of a metallic material such as copper which is the same as the material of the seal walls 24 in the element forming region 20. The vias 36 can be produced during the same process in which the seal walls 24 are produced in the same layers.

Since the metallic reinforcing pads 34a and 34b and the metallic vias 36 are connected, the anti-chipping structure 38 provides higher chipping resistance than the interlayer dielectric films 22.

As illustrated in FIG. 2, the reinforcing pads 34 stretch along edges 201 of element forming regions 20. More specifically, at least one of the reinforcing pads 34 interconnected by the vias 36 (reinforcing pad 34a in the figure) has two linear portions 341 and 342 which stretch along the same direction as the scribe line regions 30 extend and intersect each other, forming a cross shape.

In this embodiment, as illustrated in FIG. 1, the reinforcing pads 34 in the intersections 32 of the scribe line regions 30 on the outer border of the arrangement of the element forming region 20 are L-shaped or T-shaped.

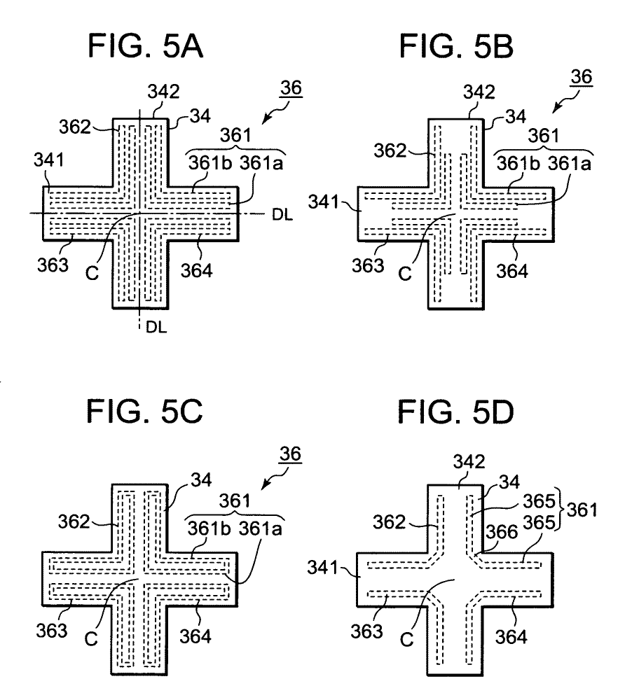

In this embodiment, as illustrated in FIGS. 5A to 5D, the anti-chipping structure 38 has several lines of vias 36 (361-364) which are spaced at intervals in the width direction of the scribe line regions 30 in parallel with each other.

More specifically, four L-shaped vias 361 to 364 lie just beneath the cross-shaped reinforcing pad 34a along the linear portions 341 and 342 with the angles (corners) of the L shapes facing each other.

The spacing between neighboring vias (361-364) is larger than the sum of the dicing blade cutting width and dicing blade positioning accuracy (hereinafter called “dicing width”).

Therefore, when dicing the semiconductor wafer 12 into semiconductor chips 10 each of which includes an element forming region 20, dicing can be performed between neighboring vias (361-364). In other words, it is unnecessary to make cuts in the metal vias 361-364 of the anti-chipping structure 38 with the dicing blade.

The reinforcing pads 34 (34a, 34b) which are stacked in layers need not always be identical in size and shape. In this embodiment, as illustrated in FIG. 3, the lower reinforcing pads 34b constitute plural lines (two lines) which are spaced in the width direction of the scribe line region 30 to match the lines of vias 36. The spacing between the reinforcing pads 34b (reinforcing pads 34b1 and 34b2) is equivalent to or larger than the dicing width.

In other words, the anti-chipping structure 38 placed in each cross-shaped intersection 32 includes an upper reinforcing pad 34a (cross-shaped as viewed from above), four lower reinforcing pads 34b (L-shaped as viewed from above), and vias 36 which interconnect the reinforcing pads 34b to the reinforcing pad 34a.

[Dicing Method]

The dicing method for the semiconductor wafer 12 according to this embodiment is explained below. This method dices the semiconductor wafer 12 to make separate semiconductor chips 10 each of which includes an element forming region 20, where the semiconductor wafer 12 has plural element forming regions 20 and mutually intersecting belt-like scribe line regions 30 which surround the element forming regions 20 respectively.

Plural interlayer dielectric films 22 are laminated in the element forming regions 20 and scribe line regions 30.

In the semiconductor wafer 12, a dicing sheet (not shown) is bonded to the back of the substrate 16 in order to prevent wafer strips or chips from scattering during the dicing process. A dicing blade is pressed against an edge of the semiconductor wafer 12 obliquely from above to make a cut in the semiconductor wafer 12 until the blade reaches halfway in the thickness of the dicing sheet.

In the semiconductor wafer 12, a structure (anti-chipping structure 38) is provided locally in at least one intersection 32 of each scribe line region 30, where the structure includes plural layers of metal pads (reinforcing pads 34) sandwiching at least one of plural interlayer dielectric films 22 vertically in the direction of lamination, and vias 36 interconnecting the reinforcing pads 34.

In this dicing method, an intersection 32 embracing an anti-chipping structure 38 is used as a dicing stroke end to separate each element forming region 20.

Also in this dicing method, at least one of the reinforcing pads 34 (34a) is used as an alignment mark for positioning the semiconductor wafer 12. Positioning of the semiconductor wafer 12 is required at various processes and this alignment mark can be used not only in the dicing process but also for alignment with a mask pattern in the photolithographic process of making a surface-protective film 42.

When a reinforcing pad 34 has a cross, L or T shape with a corner or corners as in this embodiment, optical positioning with an aligner device can be done efficiently by using the reinforcing pad 34 as an alignment mark.

When a reinforcing pad 34 embracing a center of intersection C as illustrated in FIGS. 5A to 5D is provided in an intersection 32 of scribe line regions 30 and used as an alignment mark, the reinforcing pad 34 can be used as a guide mark for dicing and also as a reinforcing means for an area where chipping easily occurs.

[Semiconductor Device]

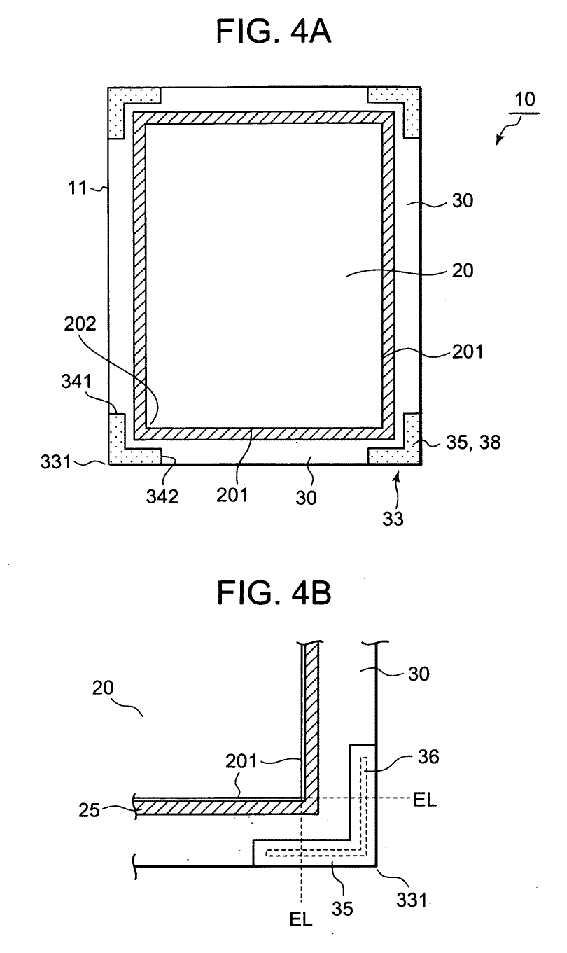

FIG. 4A is a schematic plan view of a semiconductor chip 10 obtained by dicing a semiconductor wafer 12 according to this embodiment in scribe line regions 30 and FIG. 4B shows a corner area 33 in enlarged form.

In the semiconductor wafer 12, an intersection 32 (FIG. 1) of scribe line regions 30 is diced together with reinforcing pads 34. The scribe line region 30 in which an area equivalent to the dicing width has been cut off is left on the periphery of the corresponding element forming region 20 of the semiconductor, chip 10. As a result of dicing, the scribe line region 30 of the semiconductor chip 10 becomes a belt-like region with a give width which has corner areas 33 and lies around the element forming region 20.

Furthermore, as a result of dicing, the intersection 32 in the semiconductor wafer 12 becomes a corner area 33 of the semiconductor chip 10. Similarly, the reinforcing pad 34 becomes a corner pad 35 as a result of dicing. Also as a result of dicing, the vias 36, which are spaced in the scribe line region width direction, are separated and allocated to semiconductor chips 10 respectively.

Specifically, as illustrated in FIG. 3, in this embodiment, the anti-chipping structure 38 of the semiconductor wafer 12 has two lines of vias 36 with a dicing line DL between the lines where a single reinforcing pad 34a lies over the vias 36. The two lines of vias 36 are supported by reinforcing pads 34b1 and 34b2 provided under them. Therefore, when a cut is made in the scribe line region 30 along the dicing line DL, the anti-chipping structure 38 is divided into left and right parts, each of which is allocated to a semiconductor chip 10 including an element forming region 20, as illustrated in FIG. 3.

This means that each semiconductor chip 10 in this embodiment includes an element forming region 20 and a scribe line region 30 surrounding the element forming region 20.

Plural interlayer dielectric films 22 are laminated in the element forming region 20 and scribe line region 30.

In the semiconductor chip 10, a structure (anti-chipping structure 38) is locally provided in the scribe line region 30 in at least one corner area 33, where the structure includes plural corner pads 35 sandwiching plural interlayer dielectric films 22 vertically in the direction of lamination, and vias 362 interconnecting the corner pads 35.

The semiconductor chip 10 has plural interlayer dielectric films 22 laminated in a corner area 33 and some of the interlayer dielectric films 22 are vertically sandwiched by corner pads 35 interconnected by vias 36.

In this embodiment, as illustrated in FIG. 3, the uppermost one of the interlayer dielectric films 22 is placed between reinforcing pads 34 (corner pads 35).

As illustrated in FIGS. 4A and 4B, a semiconductor element region 11, the entire area of the semiconductor chip 10, includes an element forming region 20 containing an internal circuit region (not shown), a scribe line region 30 having corner areas 33, and a seal ring region 25 lying between the element forming region 20 and scribe line region 30 and surrounding the element forming region 20.

In other words, the semiconductor chip 10 includes an anti-chipping structure 38 as well as the seal ring region 25 which prevents water penetration into the element forming region 20.

At least one of the corner pads 35 interconnected by vias 362 includes two linear portions 341 and 342 which extend along the two edges defining the corner area 33 respectively and the linear portions 341 and 342 intersect each other, forming an L shape as viewed from above.

As illustrated in FIG.2 and FIGS. 4A and 4B, the linear portions 341 and 342 of the semiconductor chip 10 extend beyond extension lines EL of the element forming region 20′ s edges 201 adjacent to the corner area 33.

In other words, the corner pad 35 lies in the immediate vicinity of the corner 331 of the semiconductor chip 10 and also extends along the corresponding edges 201 of the element forming region 20 to a point beyond the corresponding corner 202 of the element forming region 20.

In this embodiment, the semiconductor chip 10 has anti-chipping structures 38 in two or more corner areas 33 where they are away from each other.

More specifically, the semiconductor chip 10 has an anti-chipping structure 38 in each of the four corner areas 33 of the scribe line region 30.

Several lines of vias 36 extend along the same direction as the linear portions 341 and 342 of each corner pad 35.

In this embodiment, the vias 36 (361 to 364) may take the form of a series of wall-like slits (slit vias) or a series of densely spaced columns (columned vias).

However, it is possible to use various arrangements of vias 36 which will be described in connection with other embodiments.

The advantageous effect of the semiconductor wafer 12 in this embodiment is explained below.

In the semiconductor wafer 12, an anti-chipping structure 38 is provided in an intersection 32 of scribe line regions 30 to reinforce the interlayer dielectric films 22. Consequently, in the dicing process, the intersection 32 can be used as a dicing stroke end to prevent spread of chipping if any.

As stated earlier, chipping occurs due to cracking in an interlayer dielectric film 22 or peeling in an interface of an interlayer dielectric film 22. Cracking easily occurs in a fragile interlayer dielectric film 22. Chipping which has occurred at a dicing stroke end spreads inside the interlayer dielectric film 22 or in an interface thereof and stops when it hits a metallic material (anti-chipping structure 38).

Since an external binding force is given to the interlayer dielectric film 22, cracking hardly spreads in the binding direction and thus chipping hardly spreads. Since the reinforcing pads 34, which sandwich an interlayer dielectric film 22 vertically, are interconnected by vias 36, the interlayer dielectric film 22 is bound in the thickness direction. Hence, the presence of the anti-chipping structure 38 suppresses spread of chipping inside the interlayer dielectric film 22 or in an interface thereof in the vicinity of the structure.

Since this anti-chipping structure 38 does not lie on the entire periphery of the element forming region 20 but lies locally, concretely in an intersection 32, the effective area of the element forming region 20 is not affected.

In this embodiment, several lines of vias 36 are spaced at intervals in parallel with each other in the width direction of the scribe line region 30. Consequently, by moving the dicing blade in the space between vias 36 along the direction in which the scribe line region 30 extends, the wafer is diced into separate element forming regions 20 without the blade crossing the vias 36. Therefore, wear of the dicing blade is reduced.

Since the dicing blade is moved in the space between vias 36, even if chipping occurs in the scribe line region 30, the vias 36 and the reinforcing pads 34 connected with them prevent chipping from spreading further, regardless of the orientation of chipping.

In this embodiment, the reinforcing pad 34 in an intersection 32 of a scribe line region 30 has a cross shape where its two linear portions 341 and 342 extend in the same directions as the edges of the scribe line region 30 and intersect each other. Consequently, when the semiconductor wafer 12 is diced along two directions or the directions in which the edges of the scribe line region 30 extend, the cross-shaped reinforcing pad 34 is cut into four parts which are each L-shaped.

Consequently, a semiconductor chip 10 obtained by dicing the semiconductor wafer 12 has L-shaped corner pads 35 in its corner areas 33.

In this embodiment, anti-chipping structures 38 are provided in all intersections 32 where scribe line regions 30 meet. Consequently, the intersections 32 which serve as dicing stroke ends are reinforced by the anti-chipping structures 38 regardless of the dicing direction.

Next, the advantageous effect of the semiconductor chip 10 according to this embodiment is explained below.

In the semiconductor chip 10, plural corner pads 35 sandwiching at least one of the interlayer dielectric films 22 vertically in the direction of lamination, and vias 36 interconnecting the corner pads 35, are locally provided in the scribe line region of the semiconductor element region 11. More specifically, an anti-chipping structure 38 is provided in a corner area 33 of the semiconductor element region 11. Since dicing can be performed using the corner area 33 as a dicing stroke end to prevent chipping from spreading into the element forming region 20, it can be said that the semiconductor chip 10 is structured to provide a high yield rate in the dicing process.

The semiconductor chip 10 can prevent spread of chipping which has occurred in a process after the dicing process. Particularly, since the anti-chipping structure 38 lies in the corner area 33, it stops spread of chipping caused by stress concentration in the corner area due to dropping impact of the semiconductor chip 10 or another reason.

Thus, in the dicing process or a process after the dicing process, the above structure prevents chipping from spreading into the seal ring region 25 or element forming region 20, resulting in deterioration in the mechanical and electrical characteristics of the semiconductor chip 10.

In the semiconductor chip 10, some of the interlayer dielectric films 22 laminated in a corner area 33 are vertically sandwiched by corner pads 35. Considering that the possibility of chipping depends on the material and/or dicing condition of the interlayer dielectric film 22, if a specific interlayer dielectric film 22 is found to be susceptible to chipping, an anti-chipping structure 38 may be provided to sandwich the interlayer dielectric film 22 vertically, so that the number of layers of reinforcing pads 34 in the scribe line region 30 can be reduced and the yield rate of the semiconductor chip 10 in the dicing process can be improved.

In addition, in the semiconductor chip 10, the uppermost corner pad 35 laminated in the corner area 33 is connected with vias 36. The diameter of the dicing blade is much larger than the thickness of the semiconductor wafer 12 and the dicing blade first contacts the upper surface of the semiconductor wafer 12. Therefore, when an ordinary dicing blade is used, occurrence of chipping is most effectively suppressed.

The corner pads 35 connected by vias 36 each include two linear portions 341 and 342 which extend along two edges defining the corner area 33. This prevents chipping in the corner area 33 of the scribe line region 30 from bypassing the anti-chipping structure 38 and spreading toward the element forming region 20.

In this embodiment, the linear portions 341 and 342 intersect each other, forming an L shape. Thus, the anti-chipping structure 38, constituted by the L-shaped corner pads 35 and vias 36 connected with them, prevents chipping in the corner area 33 from bypassing the anti-chipping structure 38 and reaching the element forming region 20.

In this embodiment, the linear portions 341 and 342 extend beyond extension lines of the element forming region 20′ s edges 201 adjacent to the corner area 33. This further prevents chipping from bypassing the anti-chipping region 38 and reaching the element forming region 20.

The vias 36 extend in the same direction as the corner pads 35. This means that the vias 36 as well as the corner pads 35 prevent chipping from bypassing the anti-chipping structure 38 and reaching the element forming region 20. Therefore, the vias 36 effectively prevent chipping from spreading in the interlayer dielectric film 22 placed between the corner pads 35. Furthermore, the element forming region 20 has metal wirings 210 in plural interlayer dielectric films 22 and the corner pads 35 in the scribe line region 30 lie in the same layers as the metal wirings 210. The corner pads 35 are made of the same material as the metal wirings 210. Thus, the metal wirings 210 and metal pads 26 to lie inside the element forming region 20 can be produced in the same process as the reinforcing pads 34 (corner pads 35) to lie in the scribe line region 30, so that there is no increase in the number of processes for manufacturing semiconductor wafers 12 and semiconductor chips 10.

The semiconductor chip 10 has anti-chipping structures 38 in two or more corner areas 33 where they are away from each other. Specifically, as illustrated in FIG. 4A, an anti-chipping structure 38 is provided in each of the four corners of the scribe line region 30. Thus, the semiconductor chip 10 is so structured that chipping does not reach the inside of the element forming region 20, whichever corner is used as a dicing stroke end. This means that such semiconductor chips 10 can be manufactured regardless of the dicing direction.

Next, the advantageous effect of the dicing method for the semiconductor wafer 12 according to this embodiment is explained.

In this dicing method, based on the assumption that an anti-chipping structure 38 which includes plural layers of metal reinforcing pads 34 sandwiching at least one of the plural interlayer dielectric films 22 and vias 36 interconnecting the reinforcing pads 34 is locally provided in at least one intersection 32 of the scribe line region 30, dicing is performed using the intersection 32 as a dicing stroke end to separate the element forming region 20.

Since the anti-chipping structure 38 reinforces the intersection 32 as a dicing stroke end where chipping often occurs, it prevents chipping if any from spreading into the seal ring region 25 or element forming region 20.

In this dicing method, at least one reinforcing pad 34 is used as an alignment mark for positioning the semiconductor wafer 12. This means that the reinforcing pad 34 which constitutes the anti-chipping structure 38 also serves as an alignment mark. Thus, the area of the scribe line region 30 is effectively used and there is no decline in the efficiency of use of the semiconductor wafer 12.

The present invention is not limited to the above embodiment but it includes other various variations and modifications as far as the object of the present invention is achieved.

### Second Embodiment

FIGS. 5A to 5D are schematic plan views showing various variations of vias 36 in an intersection 32 of the scribe line region 30 in the semiconductor wafer 12. The cross-shaped reinforcing pads 34 and other constituent elements are the same as in the first embodiment. Several lines of vias 36 are arranged, and assuming that the linear portions 341 and 342 of a cross-shaped reinforcing pad 34 lie on orthogonal X and Y axes, vias 36 (361, 362, 363, and 364) are positioned in the four quadrants respectively as in the first embodiment. The seal ring region 25 is omitted in the figures.

The vias 36 shown in FIG. 5A extend in the same directions as the linear portions 341 and 342 of the reinforcing pad 34, namely the corner pads 35 of the semiconductor chip 10 and are arranged in four or more lines.

The corner pads 35 provided in each corner area 33 of a semiconductor chip 10 as a result of dicing are interconnected by several lines of vias 36. This further strengthens the anti-chipping structure. 38.

The lines of vias 36 (for example, vias 361a and 361b) have such a length that they extend by an equal distance from the center of intersection C of the linear portions 341 and 342.

The vias 36 shown in FIG. 5B extend in the same directions as the linear portions 341 and 342 of the reinforcing pad 34, namely the corner pads 35 of the semiconductor chip 10 and are arranged in two or more lines and the lines of vias 36 (361a, and 361b) are different in length.

In the example shown in FIG. 5B, the line of vias 361b adjacent to the element forming region 20 is longer than the line of vias 361a near the center of intersection C in the scribe line region 30.

Consequently, even if chipping in the vicinity of the center of intersection C is not stopped by the line of vias 361a, the line of vias 361b, which cover the element forming region 20 and the seal ring region 25 (FIG. 4B) more extensively, stop spread of the chipping.

In addition, since the line of vias 361a, near the dicing line DL, is short, even if the cutting face or lateral side of the dicing blade accidentally contacts the vias 36, the length of contact is short and wear of the dicing blade is reduced.

FIG. 5C shows that lines of vias 361a and 361b arranged in the shape of L are provided in each quadrant of the intersection 32 and connected with each other. Consequently, in a corner area 33 of a semiconductor chip 10 obtained by dicing the semiconductor wafer 12, there is provided an L-shaped block anti-chipping structure 38 which is constituted of vias 361a and 361b and reinforcing pads 34 placed over and under them.

Thus, the anti-chipping structure 38 of each semiconductor chip 10 is a hollow block structure with increased rigidity, so spread of chipping which occurs in the intersection 32 is prevented further effectively.

The vias 36 shown in FIG. 5D include parallel line portions 365 extending along the linear portions 341 and 342 of the reinforcing pad 34, and an oblique line portion 366 oblique to the linear portions 341 and 342. The oblique line portion 366 crosses the line segment connecting the corner 202 of the element forming region 20 and the center of intersection C of the scribe line regions 30, in a way to separate the corner 202 and the center of intersection C. The parallel line portions 365 are continuous with the oblique line portion 366.

In a semiconductor wafer 10 obtained by dicing the semiconductor wafer 12 shown in FIG. 5D, at least one of the corner pads 35 connected by vias 36 includes the oblique line portion 366 facing the corner of the scribe line region 30.

Thus, even if chipping occurs in the vicinity of the center of intersection C and is going to spread toward the corner 202 of the element forming region 20, the oblique line portion 366 of the anti-chipping structure 38, facing the chipping, effectively prevents penetration of the chipping into the element forming region 20.

### Third Embodiment

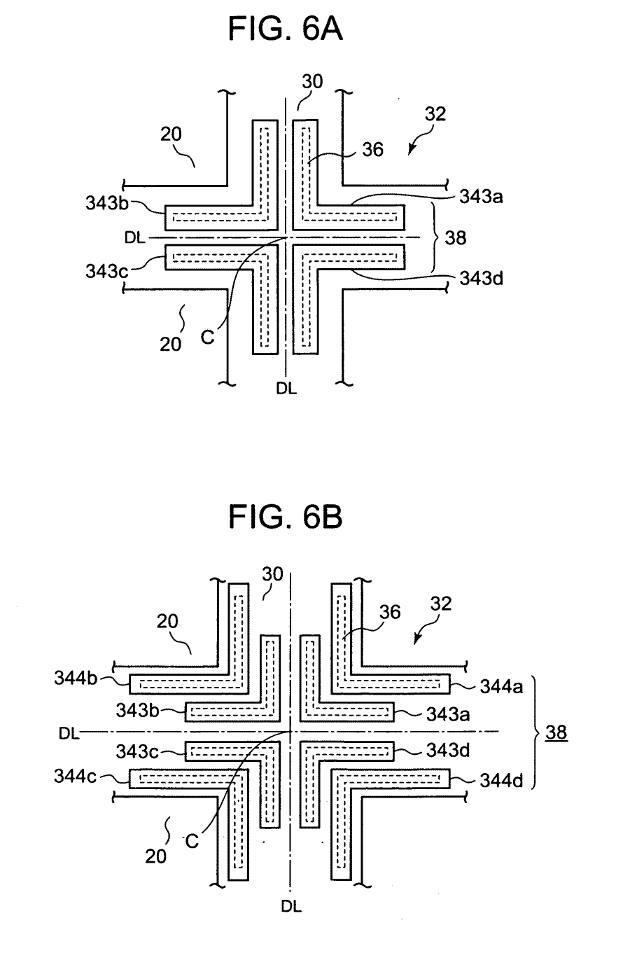

FIGS. 6A and 6B are schematic plan views showing an anti-chipping structure 38 in the semiconductor wafer 12 according to the third embodiment where the seal ring region 25 is omitted.

The anti-chipping structure 38 in an intersection 32 of scribe line regions 30 has plural reinforcing pads 34 formed separately in the same layers, between neighboring element forming regions 20 which sandwich the intersection 32.

In the anti-chipping structure 38 shown in FIG. 6A, four L-shaped sub-pads 343 (343a to 343d), mutually spaced and arranged back to back, form a cross-shaped reinforcing pad 34 in combination.

In the anti-chipping structure 32 shown in FIG. 6B, plural L-shaped sub-pads 343 (343a to 343d) and 344 (344a to 344d) are provided in each quadrant of the intersect ion 32. In other words, in a semiconductor chip 10 obtained by dicing the semiconductor wafer 12, plural corner pads 35 (sub-pads 343 and 344) formed separately in the same layers are provided between a corner 331 (FIG. 4) of the scribe line region 30 and the corresponding corner 202 of the element forming region 20.

In dicing the semiconductor wafer 12, cuts are made along dicing lines DL between sub-pads adjacent to each other (343a to 343d).

The spacing between sub-pads (343a to 343d) is larger than the dicing width.

In the semiconductor wafer 12 and semiconductor chip 10 according to the third embodiment, plural reinforcing pads 34 are formed separately in the same layers with a dicing line DL between them. The sub-pads are interconnected by vias 36.

This makes it unnecessary to cut the reinforcing pads 34 during dicing in the scribe line region 30 and thus reduces wear of the dicing blade.

Since each reinforcing pad 34 is divided into sub-pads 343 and 344 in the same layer, the stress of chipping which has reached one sub-pad is not transmitted to the other sub-pad.

### Fourth Embodiment

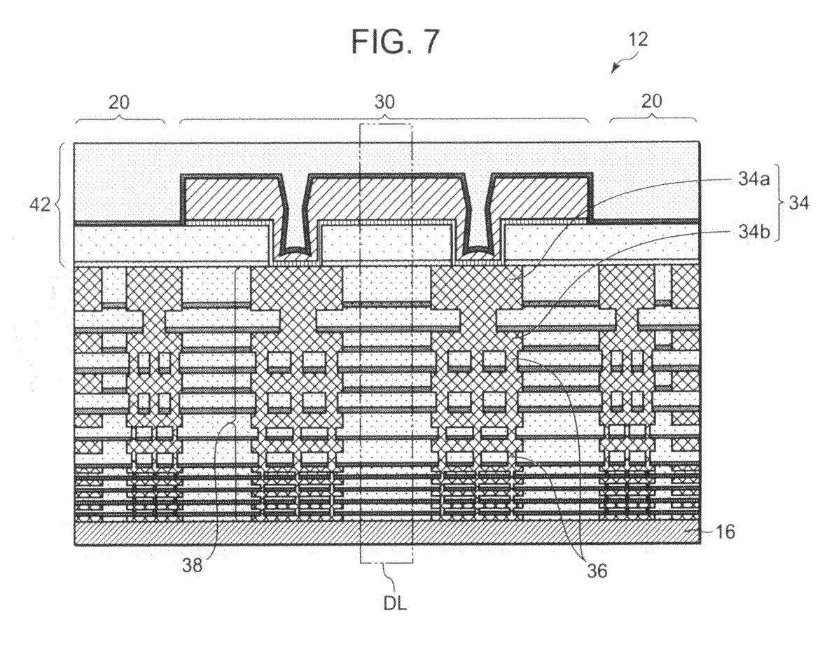

FIG. 7 is a sectional view showing the layered structure of the semiconductor wafer 12 in the fourth embodiment.

In the fourth embodiment, three or more layers of reinforcing pads 34 are laminated and the uppermost reinforcing pad 34a is connected with a lower reinforcing pad 34b by vias 36.

Therefore, in a semiconductor chip 10 obtained by making cuts in the scribe line regions 30 of the semiconductor wafer 12 along the dicing lines DL, three or more layers of corner pads 35 are laminated with an interlayer dielectric film 22 between every two such layers and the uppermost corner pad 35 is connected with a lower corner pad 35 by vias 36.

The uppermost reinforcing pad 34a may be connected with a reinforcing pad just beneath it or with a lower reinforcing pad with plural interlayer dielectric films 22 between them.

In this embodiment, the semiconductor wafer 12 has three or more layers of reinforcing pads 34 with an interlayer dielectric film 22 between every two such layers where the reinforcing pads 34 are all interconnected by vias 36.

Therefore, in a semiconductor chip 10 obtained by dicing the semiconductor wafer 12, three or more layers of corner pads 35 are laminated in the corner area 33 with an interlayer dielectric film 22 between every two such layers and all the corner pads 35 are interconnected by vias 36.

In this embodiment, every interlayer dielectric film 22 laminated over the substrate 16 lies between an upper and a lower reinforcing pad 34.

This prevents chipping at any height level in the thickness of the semiconductor wafer 12 from spreading into an interlayer dielectric film 22 or in an interface thereof and reaching the inside of the element forming region 20.

As in the third embodiment, reinforcing sub-pads 34a (34b) are mutually spaced with a dicing line DL between them in the same layer. The sub-pads 34a and 34b are connected by vias 36. Therefore, in this embodiment as well, the dicing line DL does not cross any anti-chipping structure 38 and wear of the dicing blade is reduced because it does not cut an anti-chipping structure 38.

### Fifth Embodiment

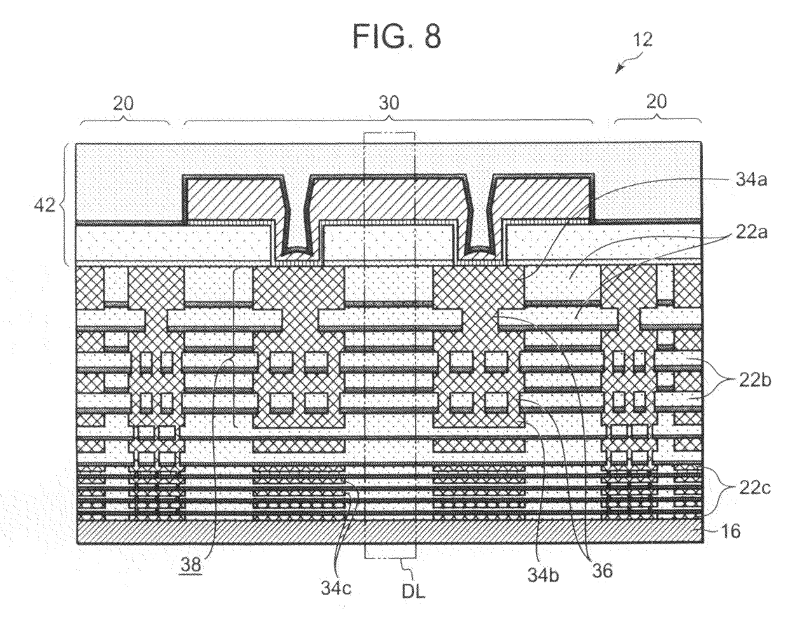

FIG. 8 is a sectional view showing the layered structure of the semiconductor wafer 12 in the fifth embodiment. In the semiconductor wafer 12 in this embodiment, three or more layers of reinforcing pads 34 are laminated with an interlayer dielectric film 22 between every two such layers and some layers of reinforcing pads 34 are interconnected by vias 36.

More specifically, only the reinforcing pads 34 that sandwich dielectric films at upper levels (all or some of the upper dielectric films 22a and intermediate dielectric films 22b) are interconnected by vias 36. The reinforcing pads 34 that sandwich dielectric films 22c at lower levels are not interconnected by vias 36.

In the fifth embodiment, however, dummy pads 34c of the same material and in the same layers as the metal wirings 210 inside the element forming region 20 are buried in the lower dielectric films 22c.

The presence of the dummy pads 34c makes it possible to use the same polishing speed in the thickness direction for the element forming region 20 and scribe line region 30 when the metal wirings 210 inside the element forming region 20 are polished to a given thickness by CMP (Chemical Mechanical Polishing).

This effect is offered not only by the dummy pads 34c but also by the reinforcing pads 34a and 34b interconnected by vias 36.

In other words, the reinforcing pads 34a and 34b which constitute the anti-chipping structure 38 function not only as means for preventing chipping but also as means for allowing the use of an equal polishing speed for the element forming region 20 and scribe line region 30.

### Sixth Embodiment

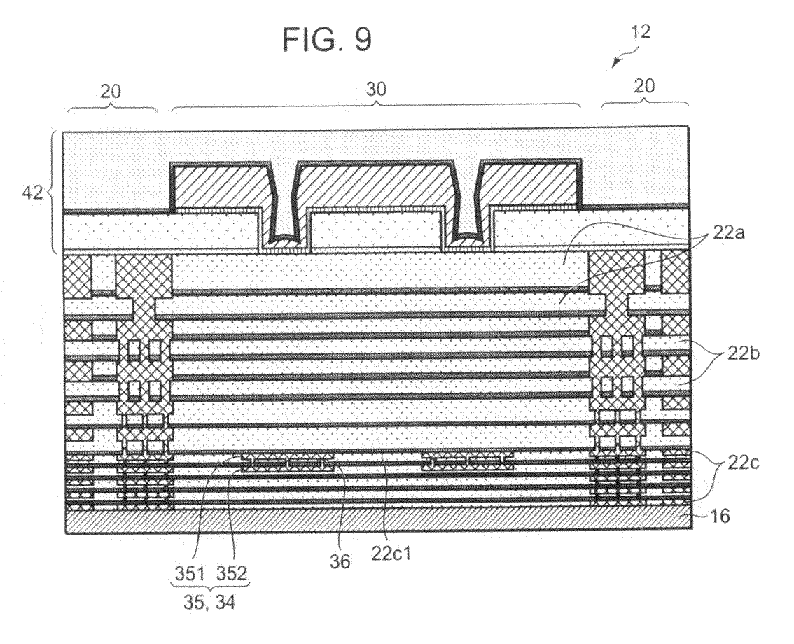

FIG. 9 is a sectional view showing the layered structure of the semiconductor wafer 12 in the sixth embodiment. In the sixth embodiment, the reinforcing pads 34 which sandwich the uppermost one among the lower porous dielectric films 22c (uppermost porous layer 22c1) are interconnected by vias 36.

In other words, in a semiconductor chip 10 obtained by dicing the semiconductor wafer 12, porous dielectric films made of a porous organic material are provided as interlayer dielectric films (lower dielectric films 22c) over the substrate 16 and porous dielectric films are sandwiched by corner pads 35. The corner pads 351 and 352 which sandwich the uppermost porous dielectric film are interconnected by vias 36.

The semiconductor wafer 12 and semiconductor chip 10 in the sixth embodiment are structured so that among layers of a fragile porous organic material (porous low-k material), the uppermost layer in which chipping is most likely to occur is reinforced by an anti-chipping structure 38.

In the sixth embodiment, not only the uppermost layer among the lower dielectric films 22c but also the uppermost layer among the interlayer dielectric films 22 (upper dielectric films 22a) may be sandwiched by reinforcing pads 34 (corner pads 35) and interconnected by vias 36.

If that is the case, since the uppermost layer among the interlayer dielectric films 22, in which chipping easily occurs during dicing, and the uppermost layer among the layers of a porous low-k material are both reinforced by anti-chipping structures 38, occurrence and spread of chipping are prevented effectively.

### Seventh Embodiment

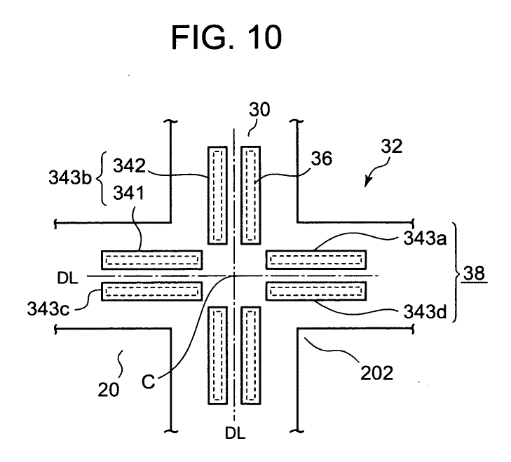

FIG. 10 is a schematic plan view showing an anti-chipping structure 38 in the semiconductor wafer 12 in the seventh embodiment, in which the seal ring region 25 is omitted.

In the anti-chipping structure 38, reinforcing pads 34 (343a to 343d) connected by vias 36 include two linear portions 341 and 342 which extend along the respective dicing lines DL.

Therefore, in a semiconductor chip 10 obtained by dicing the semiconductor wafer 12, at least one of the corner pads 35 connected by vias 36 includes two linear portions 341 and 342 which extend along two edges defining a corner area 33.

The two linear portions 341 and 342 which constitute a reinforcing pad 34 (corner pad 35) are slightly spaced mutually in the vicinity of the center of intersection C. In the semiconductor wafer 12 and semiconductor chip 10 in the seventh embodiment, there is an area where no anti-chipping structure 38 is formed, between the corner 202 of the element forming region 20 and the center of intersection C. However, the seventh embodiment also offers an effect of preventing spread of chipping in the intersection 32 because the interlayer dielectric films 22 are reinforced by the reinforcing pads 34 and vias 36 in the direction of lamination.

Several preferred embodiments of the present invention have been described so far referring to the accompanying drawings but the invention is not limited thereto and may be embodied in various other forms.

Other embodiments of the present invention are exemplified as follows:

(1) A dicing method dices a semiconductor wafer which includes plural element forming regions formed over a substrate, and belt-like scribe line regions formed over the substrate which intersect each other and respectively surround the element forming regions. In this method, the wafer is diced into semiconductor chips including the element forming regions respectively. The element forming regions and the scribe line regions include plural interlayer dielectric films laminated over the substrate, and a structure, constituted of plural metal pads sandwiching at least one of the interlayer dielectric films vertically in the direction of lamination and vias interconnecting the pads, is locally provided in at least one intersection of the scribe line regions. In this dicing method, the element forming regions are separated using an intersection embracing the above structure as a dicing stroke end.

(2) In the semiconductor wafer dicing method described in (1), at least one of the pads is used as an alignment mark to position the semiconductor wafer.

What is claimed is:

1. A semiconductor chip comprising an element forming region formed over a substrate, and a scribe line region which surrounds the element forming region,
wherein the element forming region and the scribe line region include a plurality of interlayer dielectric films laminated over the substrate; and
wherein a structure, constituted of a plurality of corner pads sandwiching at least one of the plural interlayer dielectric films vertically in a direction of lamination and vias interconnecting the corner pads, is provided locally in the scribe line region in at least one corner area of the semiconductor chip.

2. The semiconductor chip according to claim 1, wherein the element forming region has wirings in the plural interlayer dielectric films and the corner pads in the scribe line region lie in the same layers as the wirings.

3. The semiconductor chip according to claim 2, wherein the corner pads are made of the same material as the wirings.

4. The semiconductor chip according to claim 1, wherein the plural interlayer dielectric films are laminated in the corner area and some of the interlayer dielectric films are vertically sandwiched between the corner pads interconnected by the vias.

5. The semiconductor chip according to claim 1,
wherein three or more layers of the corner pads are laminated over the substrate in the corner area, respectively sandwiching the interlayer dielectric films; and
wherein the uppermost corner pad is connected with the corner pads in lower layers by the vias.

6. The semiconductor chip according to claim 1,
wherein porous dielectric films made of a porous organic material are provided as the interlayer dielectric films over the substrate in the corner area and the porous dielectric films are sandwiched by the corner pads, respectively; and
wherein the corner pads which sandwich the uppermost porous dielectric film are interconnected by the vias.

7. The semiconductor chip according to claim 1,
wherein three or more layers of the corner pads are laminated in the corner area, respectively sandwiching the. interlayer dielectric films; and
wherein all the corner pads are interconnected by the vias.

8. The semiconductor chip according to claim 1, wherein the structures are respectively provided in two or more of the corner pads and mutually spaced.

9. The semiconductor chip according to claim 1, wherein at least one of the corner pads connected by the vias includes two linear portions extending along two edges defining the corner area.

10. The semiconductor chip according to claim 9, wherein the vias extending in the same directions as the linear portions are arranged in a plurality of lines side by side.

11. The semiconductor chip according to claim 9, wherein the linear portions intersect each other and form an L shape.

12. The semiconductor chip according to claim 1, wherein at least one of the corner pads connected by the vias extend beyond extension lines of edges of the element forming region which are adjacent to the corner area.

13. The semiconductor chip according to claim 1, further comprising a seal ring region which lies between the element forming region and the scribe line region and surrounds the element forming region.

14. The semiconductor chip according to claim 13, wherein the plural corner pads, formed separately in the same layer, lie between a corner of the semiconductor chip and a corner of the seal ring region.

15. The semiconductor chip according to claim 1, wherein at least one of the corner pads connected by the vias includes an oblique line portion which extends facing a corner of the semiconductor chip.

16. A semiconductor wafer includes plural element forming regions formed over a substrate, and belt-like scribe line regions formed over the substrate which intersect each other and respectively surround the element forming regions,
wherein the element forming regions and the scribe line regions include plural interlayer dielectric films laminated over the substrate; and
wherein a structure, constituted of plural pads sandwiching at least one of the interlayer dielectric films vertically in the direction of lamination and vias interconnecting the pads, is locally provided in an intersection of the scribe line regions.

17. The semiconductor wafer according to claim 16, wherein the element forming regions have wirings in the interlayer dielectric films and the pads in the scribe line regions lie in the same layers as the wirings.

18. The semiconductor wafer according to claim 16, wherein the scribe line regions have the interlayer dielectric films laminated therein and some of the interlayer dielectric films are vertically sandwiched by the pads interconnected by the vias

19. The semiconductor wafer according to claim 16, wherein the plural lines of vias are spaced at intervals and parallel to each other in the width directions of the scribe line regions.

20. The semiconductor wafer according to claim 16, wherein at least one of the pads connected by the vias has a cross shape in which two linear portions, extending in the same directions as the scribe line regions respectively, intersect each other.

21. The semiconductor wafer according to claim 16, wherein a seal ring region which surrounds the element forming region is provided between the element forming region and the scribe line region.

22. The semiconductor wafer according to claim 16, wherein the structure is provided in every intersection of the scribe line regions.
